(19) United States
(12) Patent Application Publication
(10) Pub. No.: US 2024/0260342 A1
(43) Pub. Date: Aug. 1, 2024

(54) DISPLAY PANEL AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Youngyik KO, Beijing (CN); Mengmeng DU, Beijing (CN); Xiangdan DONG, Beijing (CN); Biao LIU, Beijing (CN); Xiaoqing SHU, Beijing (CN); Hongwei MA, Beijing (CN)

(21) Appl. No.: 18/016,473

(22) PCT Filed: Aug. 24, 2021
(86) PCT No.: PCT/CN2021/114350

§ 371 Date: Jan. 17, 2023

(51) Int. Cl. H10K 59/131; G09G 3/3233

(52) U.S. Cl. CPC H10K 59/131; G09G 3/3233; G09G 2300/0819; G09G 2300/0842; G09G 2300/0861; G09G 2310/08; G09G 2320/0223

(57) ABSTRACT

A display panel includes: a base substrate, a third conductive layer, and a fourth conductive layer. The third conductive layer is located on one side of the base substrate and includes multiple first signal lines, where orthographic projections of the first signal lines on the base substrate are spaced apart in a first direction and extend along a second direction, and the first direction intersects with the second direction. The fourth conductive layer is located on the side of the third conductive layer away from the base substrate and includes multiple connection line segments, where orthographic projections of the connection line segments on the base substrate extend along the first direction, and a same connection line segment is respectively connected to a plurality of first signal lines through via holes.

### TECHNICAL FIELD

The present disclosure relates to the field of display technology, and in particular, to a display panel and a display device.

### BACKGROUND

In the related art, a display panel includes a variety of signal lines, such as power lines, initial signal lines, and the like. Due to the voltage drop in the signal lines such as the power lines, so that the signal lines would represent different voltages at different positions of the display panel, thereby causing uneven displaying of the display panel.

It should be noted that the information disclosed in this section is only for enhancing understanding the background of the disclosure and therefore may contain information not belonging to the prior art that is already known to those skilled in the art.

### SUMMARY

According to a first aspect of the disclosure, a display panel is provided. The display panel includes a base substrate, a third conductive layer and a fourth conductive layer. The third conductive layer is located on one side of the base substrate and includes first signal lines, where orthographic projections of the first signal lines on the base substrate are spaced apart in a first direction and extend along a second direction, and the first direction intersects with the second direction. The fourth conductive layer is located on one side of the third conductive layer away from the base substrate and includes connection line segments, where orthographic projections of the connection line segments on the base substrate extend along the first direction, and a same one of the connection line segments is connected to multiple ones of the first signal lines through via holes, respectively.

In some embodiments of the disclosure, the first signal line is a power line.

In some embodiments of the disclosure, the display panel further includes pixel driving circuits arranged in the first direction and the second direction, and the pixel driving circuit includes a driving transistor, a capacitor and a fourth transistor. A first electrode of the capacitor is connected to a gate of the driving transistor, and a second electrode of the capacitor is connected to a power line. A second electrode of the fourth transistor is connected to a first electrode of the driving transistor, and a first electrode of the fourth transistor is connected to a data line. The display panel further includes a first conductive layer and a second conductive layer. The first conductive layer is located between the base substrate and the third conductive layer, where the first conductive layer includes first conductive parts, orthographic projections of the first conductive parts on the base substrate are spaced apart in the first direction, and the first conductive parts are used to form the gate of the driving transistor and the first electrode of the capacitor. The second conductive layer is located between the first conductive layer and the third conductive layer, where the second conductive layer includes second conductive parts, orthographic projections of the second conductive parts on the base substrate are spaced apart in the first direction, the second conductive parts are provided in a one-to-one correspondence with the first conductive parts, the orthographic projections of the second conductive parts on the base substrate at least partially overlaps with orthographic projections of corresponding first conductive parts on the base substrate, and the second conductive parts are used to form the second electrode of the capacitor. The third conductive layer further includes the data line, where an orthographic projection of the data line on the base substrate extends along the second direction, and the orthographic projection of the data line on the base substrate is located between orthographic projections of two second conductive parts adjacent in the first direction on the base substrate.

In some embodiments of the disclosure, the orthographic projection of the data line on the base substrate intersects with the orthographic projections of the connection line segments on the base substrate; and the display panel further includes a dielectric layer and a planarization layer. The dielectric layer is located between the second conductive layer and the third conductive layer. The planarization layer is located between the third conductive layer and the fourth conductive layer, where a thickness of the planarization layer is greater than a thickness of the dielectric layer.

In some embodiments of the disclosure, the first direction is a row direction, the second direction is a column direction, and the fourth conductive layer includes the connection line segments arranged in the row direction and the column direction. The connection line segments located in a same row are spaced apart in the row direction, and adjacent connection line segments in the same row are connected to different ones of the first signal lines. The connection line segments located in a same column are spaced apart in the column direction, and the connection line segments in the same column are connected to a same group of the first signal lines. The connection line segments of adjacent rows and adjacent columns are staggered in the first direction, and the staggered connection line segments are commonly connected to at least one of the first signal lines.

In some embodiments of the disclosure, each connection line segment is connected to four adjacent first signal lines, and the staggered connection line segments are commonly connected to two adjacent first signal lines.

In some embodiments of the disclosure, the display panel includes pixel driving circuits arranged in rows and columns. The first signal lines are provided in a one-to-one correspondence with multiple columns of the pixel driving circuits, and the pixel driving circuits are connected to corresponding first signal lines. Multiple rows of the connection line segments are provided in a one-to-one correspondence with multiple rows of the pixel driving circuits, and an orthographic projection of at least a partial structure of the connection line segments on the base substrate is located within an orthographic projection of a corresponding row of the pixel driving circuits on the base substrate.

In some embodiments of the disclosure, the first direction is a row direction, the second direction is a column direction, the display panel includes pixel driving circuits arranged in rows and columns, the first signal lines are provided in a one-to-one correspondence with multiple columns of the pixel driving circuits, and the pixel driving circuits are connected to corresponding first signal lines. The pixel driving circuits include a first pixel driving circuit, a second pixel driving circuit, a third pixel driving circuit and a fourth pixel driving circuit arranged adjacently in sequence along the first direction. The first signal lines include a first signal sub-line, a second signal sub-line, a third signal sub-line and a fourth signal sub-line, where the first signal sub-line is provided corresponding to the first pixel driving circuit, the second signal sub-line is provided corresponding to the second pixel driving circuit, the third signal sub-line is provided corresponding to the third pixel driving circuit, and the fourth signal sub-line is provided corresponding to the fourth pixel driving circuit. The connection line segments include a first connection line segment, where the first connection line segment is respectively connected to the first signal sub-line, the second signal sub-line, the third signal sub-line and the fourth signal sub-line through via holes, and an orthographic projection of the first connection line segment on the base substrate at least partially intersects with an orthographic projection of the second pixel driving circuit on the base substrate.

In some embodiments of the disclosure, the pixel driving circuit includes a driving transistor and a second transistor, a first electrode of the second transistor is connected to a first electrode of the driving transistor, and a second electrode of the second transistor is connected to a gate of the driving transistor. The display panel further includes an active layer located between the base substrate and the third conductive layer, where the active layer includes an eighth active part, an orthographic projection of the eighth active part on the base substrate extends along the first direction, and at least a partial structure of the eighth active part is used to form a first channel region of the second transistor. The first connection line segment includes a first extension part, where an orthographic projection of the first extension part on the base substrate extends along the first direction, a first end of the first extension part is connected to the first signal sub-line through a via hole, a second end of the first extension part is connected to the second signal sub-line through a via hole, and the orthographic projection of the first extension part on the base substrate covers an orthographic projection of the eighth active part in the second pixel driving circuit on the base substrate.

In some embodiments of the disclosure, the pixel driving circuit further includes a driving transistor and a fourth transistor, a second electrode of the fourth transistor is connected to a second electrode of the driving transistor, and a first electrode of the fourth transistor is connected to a data line. The display panel further includes an active layer located between the base substrate and the third conductive layer, where the active layer further includes a fourth active part and a ninth active part, where the fourth active part is used to form a channel region of the fourth transistor; and the ninth active part is connected between the fourth active part and the data line. The first connection line segment further includes a second extension part, where an orthographic projection of the second extension part on the base substrate at least partially overlaps with an orthographic projection of the ninth active part in the second pixel driving circuit on the base substrate.

In some embodiments of the disclosure, the pixel driving circuit further includes a driving transistor and a first transistor, a first electrode of the first transistor is connected to a gate of the driving transistor, and a second electrode of the first transistor is connected to a first initial signal line. The third conductive layer further includes a first connection part, where the first connection part is connected between the first initial signal line and the second electrode of the first transistor, and an orthographic projection of the first connection part on the base substrate extends along the second direction. The first connection line segment includes a third extension part, where an orthographic projection of the third extension part on the base substrate extends along the second direction, and the orthographic projection of the third extension part on the base substrate at least partially overlaps with an orthographic projection of the first connection part in the third pixel driving circuit on the base substrate.

In some embodiments of the disclosure, the pixel driving circuit further includes a driving transistor and a first transistor, a first electrode of the first transistor is connected to a gate of the driving transistor, and a second electrode of the first transistor is connected to a first initial signal line. The display panel further includes an active layer located between the base substrate and the third conductive layer, where the active layer includes a tenth active part, an eleventh active part, and a twelfth active part, the tenth active part is used to form a first channel region of the first transistor, the eleventh active part is used to form a second channel region of the first transistor, the twelfth active part is connected between the tenth active part and the eleventh active part, and an orthographic projection of the twelfth active part on the base substrate extends along the first direction. The first connection line segment includes a fourth extension part, where an orthographic projection of the fourth extension part on the base substrate extends along the first direction, and the orthographic projection of the fourth extension part on the base substrate at least partially overlaps with an orthographic projection of the twelfth active part in the third pixel driving circuit on the base substrate.

In some embodiments of the disclosure, the pixel driving circuit further includes a driving transistor and a first transistor, a first electrode of the first transistor is connected to a gate of the driving transistor, and a second electrode of the first transistor is connected to a first initial signal line. The display panel further includes a second conductive layer located between the base substrate and the third conductive layer, where the second conductive layer includes first initial signal lines, orthographic projections of the first initial signal lines on the base substrate extend along the first direction and are spaced apart in the second direction, the first initial signal lines are provided in a one-to-one correspondence with multiple rows of the pixel driving circuits, and the first transistors in the pixel driving circuits are connected to corresponding first initial signal lines. The third conductive layer includes second initial signal lines, where orthographic projections of the second initial signal lines on the base substrate extend along the second direction and are spaced apart in the first direction, and the first initial signal lines are connected to the second initial signal lines intersected therewith through via holes.

In some embodiments of the disclosure, the second initial signal lines include a first initial signal sub-line, and an orthographic projection of the first initial signal sub-line on the base substrate at least partially overlaps with an orthographic projection of the fourth pixel driving circuit on the base substrate. The first initial signal lines include a second initial signal sub-line corresponding to the fourth pixel driving circuit. The first connection line segment includes a fifth extension part and a sixth extension part, where an orthographic projection of the fifth extension part on the base substrate at least partially overlaps with the orthographic projection of the first initial signal sub-line on the base substrate; and an orthographic projection of the sixth extension part on the base substrate at least partially overlaps with an orthographic projection of the second initial signal sub-line on the base substrate.

In some embodiments of the disclosure, the pixel driving circuit includes a driving transistor, a first transistor, a second transistor, and a fourth transistor; a first electrode of the first transistor is connected to a gate of the driving transistor, a second electrode of the first transistor is connected to the first initial signal line; a first electrode of the second transistor is connected to a first electrode of the driving transistor, a second electrode of the second transistor is connected to the gate of the driving transistor; a second electrode of the fourth transistor is connected to a second electrode of the driving transistor, and a first electrode of the fourth transistor is connected to a data line. The display panel further includes a first conductive layer, a second conductive layer and an active layer. The first conductive layer is located between the base substrate and the third conductive layer. The second conductive layer is located between the first conductive layer and the third conductive layer, where the second conductive layer includes first initial signal lines, orthographic projections of the first initial signal lines on the base substrate extend along the first direction and are spaced apart in the second direction, the first initial signal lines are provided in a one-to-one correspondence with multiple rows of the pixel driving circuits, and the first transistors in the pixel driving circuits are connected to corresponding first initial signal lines. The active layer is located between the base substrate and the first conductive layer, and includes a fourth active part, an eighth active part, a ninth active part, a tenth active part, an eleventh active part and a twelfth active part; where the fourth active part is used to form a channel region of the fourth transistor; the ninth active part is connected between the fourth active part and the data line; an orthographic projection of the eighth active part on the base substrate extends along the first direction, at least a partial structure of the eighth active part is used to form a first channel region of the second transistor; the tenth active part is used to form a first channel region of the first transistor; the eleventh active part is used to form a second channel region of the first transistor; the twelfth active part is connected between the tenth active part and the eleventh active part, and an orthographic projection of the twelfth active part on the base substrate extends along the first direction. The third conductive layer includes second initial signal lines and a first connection part, where orthographic projections of the second initial signal lines on the base substrate extend along the second direction and are spaced in the first direction, and the second initial signal lines are connected to the first initial signal lines intersecting therewith through via holes; the first connection part is connected between the initial signal line and the second electrode of the first transistor, and an orthographic projection of the first connection part on the base substrate extends along the second direction. The first connection line segment includes a first extension part, a second extension part, a third extension part, a fourth extension part, a fifth extension part, and a sixth extension part connected in sequence. An orthographic projection of the first extension part on the base substrate extends along the first direction, a first end of the first extension part is connected to the first signal sub-line through a via hole, a second end of the first extension part is connected to the second signal sub-line through a via hole, and the orthographic projection of the first extension part on the base substrate covers the orthographic projection of the eighth active part in the second pixel driving circuit on the base substrate. An orthographic projection of the second extension part on the base substrate at least partially overlaps with an orthographic projection of the ninth active part in the second pixel driving circuit on the base substrate, and an included angle between the orthographic projection of the second extension part on the base substrate and the orthographic projection of the first extension part on the base substrate is an obtuse angle. An orthographic projection of the third extension part on the base substrate extends along the second direction, and the orthographic projection of the third extension part on the base substrate at least partially overlaps with the orthographic projection of the first connection part in the third pixel driving circuit on the base substrate. An orthographic projection of the fourth extension part on the base substrate extends along the first direction, and the orthographic projection of the fourth extension part on the base substrate at least partially overlaps with the orthographic projection of the twelfth active part in the third pixel driving circuit on the base substrate. The second initial signal lines include a first initial signal sub-line, where an orthographic projection of the first initial signal sub-line on the base substrate at least partially overlaps with an orthographic projection of the fourth pixel driving circuit on the base substrate. The first initial signal lines include a second initial signal sub-line corresponding to the fourth pixel driving circuit. The first connection line segment further includes the fifth extension part and the sixth extension part, where an orthographic projection of the fifth extension part on the base substrate at least partially overlaps with the orthographic projection of the first initial signal sub-line on the base substrate; and an orthographic projection of the sixth extension part on the base substrate at least partially overlaps with the orthographic projection of the second initial signal sub-line on the base substrate.

In some embodiments of the disclosure, the display panel further includes light-emitting units, the fourth conductive layer further includes electrode parts arranged in rows and columns, and the electrode parts are used to form electrodes of light-emitting units. The electrode parts include red (R) electrode parts, green (G) electrode parts and blue (B) electrode parts alternately distributed in sequence along a same one of electrode rows. In the same one of the electrode rows, two G electrode parts are arranged in the column direction between the R electrode part and the B electrode part; in two adjacent electrode rows, the electrode parts of a same color are located in different columns; and in two electrode rows with one electrode row therebetween, the electrode parts of a same color are located in a same column. The electrode rows include a first electrode row, the first electrode row includes a first R electrode part, a first G electrode part and a second G electrode part arranged in the column direction, and a first B electrode part that are arranged adjacently in the row direction, where the first G electrode part and the second G electrode part are located in a same electrode column, the first R electrode part forms the R electrode part, the first G electrode part and the second G electrode part form the G electrode part, and the first B electrode part forms the B electrode part. The first R electrode part is connected to the first pixel driving circuit, the second G electrode part is connected to the second pixel driving circuit, and the first B electrode part is connected to the third pixel driving circuit. The orthographic projection of the first extension part on the base substrate is located between an orthographic projection of the first G electrode part on the base substrate and an orthographic projection of the second G electrode part on the base substrate. The third conductive layer further includes second connection parts, the second connection parts are connected to the electrode parts through via holes, the second connection parts include a first connection sub-part, and the first connection sub-part is connected to the first B electrode part. The orthographic projection of the fourth extension part on the base substrate, the orthographic projection of the fifth extension part on the base substrate, and the orthographic projection of the sixth extension part on the base substrate are located on a side of an orthographic projection of the first B electrode part on the base substrate away from an orthographic projection of the first connection sub-part on the base substrate.

In some embodiments of the disclosure, the pixel driving circuit includes a driving transistor and a fourth transistor, a second electrode of the fourth transistor is connected to a second electrode of the driving transistor, and a first electrode of the fourth transistor is connected to a data line. The display panel further includes an active layer located between the base substrate and the first conductive layer, where the active layer includes a thirteenth active part connected to a gate of the driving transistor, and an orthographic projection of the thirteenth active part on the base substrate extends along the second direction. The second conductive layer further includes third conductive parts connected to a stable voltage source, and the third conductive part includes a first conductive sub-part, where an orthographic projection of the first conductive sub-part on the base substrate extends along the second direction, and is located between the orthographic projection of the thirteenth active part on the base substrate and an orthographic projection of the data line on the base substrate.

In some embodiments of the disclosure, the pixel driving circuit further includes a second transistor, where a first electrode of the second transistor is connected to a first electrode of the driving transistor, a second electrode of the second transistor is connected to a gate of the driving transistor. The active layer further includes a sixteenth active part, a fourteenth active part and a fifteenth active part, where the sixteenth active part is used to form a first channel region of the second transistor; the fourteenth active part is used to form a second channel region of the second transistor; and the fifteenth active part is connected between the sixteenth active part and the fourteenth active part. The third conductive part further includes a second conductive sub-part connected to the first conductive sub-part, where an orthographic projection of the second conductive sub-part on the base substrate at least partially overlaps with an orthographic projection of the fifteenth active part on the base substrate.

In some embodiments of the disclosure, the first direction is a row direction, the second direction is a column direction, the display panel further includes pixel driving circuits arranged in rows and columns, and the pixel driving circuit includes a driving transistor, a first transistor, a second transistor, a fourth transistor, a fifth transistor, a sixth transistor, and a seventh transistor. The first transistor is provided with a first electrode connected to a gate of the driving transistor, a second electrode connected to a first initial signal line, and a gate connected to a reset signal line. The second transistor is provided with a first electrode connected to a first electrode of the driving transistor, a second electrode connected to the gate of the driving transistor, and a gate connected to a gate driving signal line. The fourth transistor is provided with a second electrode connected to a second electrode of the driving transistor, a first electrode connected to a data line, and a gate connected to the gate driving signal line. The fifth transistor is provided with a first electrode connected to a power line, a second electrode connected to the second electrode of the driving transistor, and a gate connected to an enable signal line. The sixth transistor is provided with a first electrode connected to the first electrode of the driving transistor, and a gate connected to the enable signal line. The seventh transistor is provided with a first electrode connected to a first initial signal line in a pixel driving circuit of a next row, a second electrode connected to a second electrode of the sixth transistor, and a gate connected to a reset signal line in the pixel driving circuit of the next row. The display panel includes a first conductive layer including the enable signal line, the gate driving signal line, and the reset signal line, where an orthographic projection of the enable signal line on the base substrate, an orthographic projection of the gate driving signal line on the base substrate, and an orthographic projection of the reset signal line on the base substrate extend along the first direction. The enable signal line includes a seventh extension part and an eighth extension part alternately connected in sequence; where in the second direction, a size of an orthographic projection of the seventh extension part on the base substrate is smaller than a size of an orthographic projection of the eight extension part on the base substrate; and the orthographic projection of the seventh extension part on the base substrate intersects with the orthographic projection of the data line on the base substrate. The gate driving signal line includes a ninth extension part and a tenth extension part alternately connected in sequence; where in the second direction, a size of an orthographic projection of the ninth extension part on the base substrate is smaller than a size of an orthographic projection of the tenth extension part on the base substrate; and the orthographic projection of the ninth extension part on the base substrate intersects with the orthographic projection of the data line on the base substrate. The reset signal line includes an eleventh extension part and a twelfth extension part alternately connected in sequence; where in the second direction, a size of an orthographic projection of the eleventh extension part on the base substrate is smaller than a size of an orthographic projection of the twelfth extension part on the base substrate; and the orthographic projection of the eleventh extension part on the base substrate intersects with the orthographic projection of the data line on the base substrate.

According to another aspect of the disclosure, a display device is provided, where the display device includes the display panel as described above.

It should be understood that the foregoing general description and the following detailed description are exemplary and explanatory only and are not restrictive of the disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Obviously, the drawings in the following description are only some embodiments of the present disclosure, and for those of ordinary skill in the art, other drawings may also be obtained from these drawings without creative effort.

FIG. 1 is a schematic diagram illustrating a circuit structure of a pixel driving circuit in a display panel according to some embodiments of the present disclosure.

FIG. 2 is a timing diagram of each node in a driving method of the pixel driving circuit in FIG. 1.

FIG. 3 is a structural layout of a display panel according to some embodiments of the present disclosure.

FIG. 4 is a structural layout of a display panel in the related art.

FIG. 5 is a structural layout of a display panel according to some other embodiments of the present disclosure.

FIG. 6 is a structural layout of the first conductive layer in FIG. 5.

FIG. 7 is a structural layout of the second conductive layer in FIG. 5.

FIG. 8 is a structural layout of the third conductive layer in FIG. 5.

FIG. 9 is a structural layout of the fourth conductive layer in FIG. 5.

FIG. 10 is a structural layout of a display panel according to some other embodiments of the present disclosure.

FIG. 11 is a structural layout of the active layer in FIG. 10.

FIG. 12 is a structural layout of the first conductive layer in FIG. 10.

FIG. 13 is a structural layout of the second conductive layer in FIG. 10.

FIG. 14 is a structural layout of the third conductive layer in FIG. 10.

FIG. 15 is a structural layout of the fourth conductive layer in FIG. 10.

FIG. 16 is a structural layout of the active layer and the first conductive layer in FIG. 10.

FIG. 17 is a structural layout of the active layer, the first conductive layer, and the second conductive layer in FIG. 10.

FIG. 18 is a structural layout of the active layer, the first conductive layer, the second conductive layer, and the third conductive layer in FIG. 10.

FIG. 19 is a partial cross-sectional view taken along dotted line A in FIG. 10.

FIG. 20 is a structural layout of a fourth conductive layer in a display panel according to some other embodiments of the present disclosure.

FIG. 21 is a structural layout of a fourth conductive layer in a display panel according to some other embodiments of the present disclosure.

### DETAILED DESCRIPTION

Exemplary embodiments will now be described more fully with reference to the accompanying drawings. Exemplary embodiments, however, may be implemented in various forms and should not be construed as limited to the examples set forth herein. Instead, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted.

The terms “a”, “an”, “the” are used to indicate the presence of one or more elements/components/and the like; the terms “include” and “have” are used to indicate an open-ended inclusive meaning and refer to additional elements/components/and the like may be present in addition to the elements/components/and the like as listed herein.

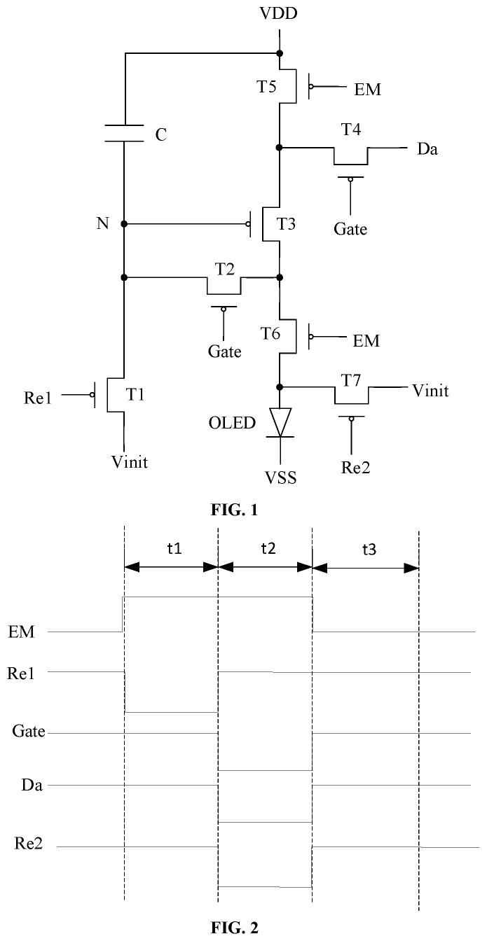

As shown in FIG. 1, it is a schematic diagram illustrating a circuit structure of a pixel driving circuit in a display panel according to some embodiments of the present disclosure. The pixel driving circuit may include: a first transistor T1, a second transistor T2, a driving transistor T3, a fourth transistor T4, a fifth transistor T5, a sixth transistor T6, a seventh transistor T7, and a capacitor C. The first electrode of the first transistor T1 is connected to the node N, the second electrode thereof is connected to the initial signal terminal Vinit, and the gate thereof is connected to the reset signal terminal Re1. The first electrode of the second transistor T2 is connected to the first electrode of the driving transistor T3, the second electrode thereof is connected to the node N, and the gate thereof is connected to the gate driving signal terminal Gate. The gate of the driving transistor T3 is connected to the node N. The first electrode of the fourth transistor T4 is connected to the data signal terminal Da, the second electrode thereof is connected to the second electrode of the driving transistor T3, and the gate thereof is connected to the gate driving signal terminal Gate. The first electrode of the fifth transistor T5 is connected to the first power supply terminal VDD, the second electrode thereof is connected to the second electrode of the driving transistor T3, and the gate thereof is connected to the enable signal terminal EM. The first electrode of the sixth transistor T6 is connected to the first electrode of the driving transistor T3, and the gate thereof is connected to the enable signal terminal EM. The first electrode of the seventh transistor T7 is connected to the initial signal terminal Vinit, the second electrode thereof is connected to the second electrode of the sixth transistor T6, and the gate thereof is connected to the reset signal terminal Re2. The capacitor C is connected between the gate of the driving transistor T3 and the first power supply terminal VDD. The pixel driving circuit may be connected to a light-emitting unit OLED for driving the light-emitting unit OLED to emit light, and the light-emitting unit OLED may be connected between the second electrode of the sixth transistor T6 and the second power terminal VSS. In some embodiments, the transistors T1-T7 may all be P-type transistors.

As shown in FIG. 2, it is a timing diagram of each node in a driving method of the pixel driving circuit in FIG. 1, where Gate represents the timing of the gate driving signal terminal Gate, Re1 represents the timing of the reset signal terminal Re1, Re2 represents the timing of the reset signal terminal Re2, EM represents the timing of the enable signal terminal EM, and Da represents the timing of the data signal terminal Da. The driving method of the pixel driving circuit may include a reset stage t1, a compensation stage t2, and a light-emitting stage t3. In the reset stage t1, the reset signal terminal Re1 outputs a low level signal; the first transistor T1 is turned on; and the initial signal terminal Vinit inputs an initial signal to the node N. In the compensation stage t2, the reset signal terminal Re2 and the gate driving signal terminal Gate output a low-level signal; the fourth transistor T4, the second transistor T2, and the seventh transistor T7 are turned on; the data signal terminal Da outputs a driving signal to write voltage Vdata+Vth to the node N, where Vdata is the voltage of the driving signal, Vth is the threshold voltage of the driving transistor T3; and the initial signal terminal Vinit inputs the initial signal to the second electrode of the sixth transistor T6. In the light-emitting stage t3, the enable signal terminal EM outputs a low-level signal; the sixth transistor T6 and the fifth transistor T5 are turned on; and the driving transistor T3 emits light under the action of the voltage Vdata+Vth stored in the capacitor C. According to a formula representing an output current of the driving transistor, that is I=(μWCox/2L)(Vgs−Vth)2, where is the carrier mobility, Cox is the gate capacitance per unit area, W is the channel width of the driving transistor, L is the channel length of the driving transistor, Vgs is the gate-source voltage difference of the driving transistor, and Vth is the threshold voltage of the driving transistor; the output current of the driving transistor in the pixel driving circuit of the present disclosure is I=(μWCox/2L)(Vdata+Vth−Vdd−Vth)2. Based on the pixel driving circuit, the influence of the threshold value of the driving transistor on its output current may be avoided.

Some embodiments provide a display panel, as shown in FIG. 3, which is a structural layout of a display panel according to some embodiments of the present disclosure. In some embodiments, the display panel includes a base substrate, a third conductive layer, and a fourth conductive layer. The third conductive layer is located on one side of the base substrate, and the third conductive layer may include a plurality of first signal lines VDD, and the orthographic projections of the plurality of first signal lines VDD on the base substrate are spaced apart in the first direction X and extend along the second direction Y, where the first direction X intersects with the first direction X. For example, the first direction may be perpendicular to the second direction. The fourth conductive layer is located on the side of the third conductive layer away from the base substrate, and the fourth conductive layer may include a plurality of connection line segments 4, the orthographic projection of the connection line segments 4 on the base substrate may extend along the first direction X, and the same connection line segment 4 may be connected to multiple first signal lines VDD through via holes H (black squares in the drawings) respectively.

In some embodiments of the display panel, a plurality of first signal lines VDD are connected with the connection line segment 4, so that the first signal lines VDD form a grid structure, thereby reducing the voltage drop of the first signal lines, and improving the display uniformity of the display panel.

It should be noted that, when referring to that the orthographic projection of the connection line segment 4 on the base substrate extends along the first direction X, it may be understood as the orthographic projection of the connection line segment 4 on the base substrate extends along the first direction X as a whole. In other words, the orthographic projection of the connection line segment 4 on the base substrate may extend in a straight line or a bent line along the first direction X.

In some embodiments, the first signal line VDD may be a power supply line, and the power supply line may be used to provide driving power to a pixel driving circuit in the display panel. For example, the display panel in some embodiments may include the pixel driving circuit shown in FIG. 1, and the power line may be used to provide the first power terminal VDD in FIG. 1. The fourth conductive layer may be an electrode layer, the fourth conductive layer may also include a plurality of electrode parts, and the electrode parts may be used to form electrodes of the light-emitting units in the display panel. For example, the electrode parts may be used to form anodes of the light-emitting units in the display panel. It should be understood that, in some other embodiments, the first signal lines may also be other signal lines. For example, the first signal line may be an initial signal line, and the initial signal line may be used to provide an initial signal to the pixel driving circuit. For example, the initial signal line may be used to provide the initial signal terminal Vinit in FIG. 1. The fourth conductive layer may also be other conductive layers, for example, the fourth conductive layer may be other conductive layers added between the third conductive layer and the electrode layer. In addition, the display panel may further include pixel driving circuits of other structures, for example, the pixel driving circuits may be implemented in 2T1C, 8T1C, 9T1C and other structures.

In some embodiments, the first direction X may be a row direction, and the second direction Y may be a column direction. As shown in FIG. 3, the fourth conductive layer may include a plurality of connection line segments 4, the orthographic projection of the connection line segments 4 on the base substrate may intersect with the orthographic projection of the first signal lines VDD on the base substrate, a connection line segment 4 may be connected to a first signal line VDD intersected therewith through a via hole, and each connection line segment may be connected to a same number of first signal lines VDD. The connection line segments 4 located in the same row may be spaced apart in the row direction, and adjacent connection line segments 4 in the same row of connection line segments 4 may be connected to different first signal lines VDD. The connection line segments 4 located in the same column may be spaced apart in the column direction, and the connection line segments in the same column may be connected to a same group of the first signal lines VDD. The connection line segments 4 in adjacent rows and columns may be staggered in the first direction X, and the staggered connection line segments 4 are commonly connected to at least one of the first signal lines VDD. Herein, when referring to that the connection line segments 4 in adjacent rows and adjacent columns may be staggered in the first direction X, it may be understood as the orthographic projections of the connection line segments in adjacent rows and adjacent columns on the base substrate would intersects with each other when their coverage area are moved along the second direction Y In some embodiments, the first signal line VDD is connected to the connection line segments 4 that are spaced apart, so that sufficient layout space can be reserved for the electrode parts in the fourth conductive layer. In addition, the connection line segments 4 in adjacent rows and adjacent columns are staggered in the first direction X, so that different first signal lines VDD may be connected to form an integral structure, thereby greatly reducing the voltage drop on the first signal lines VDD. In some embodiments, as shown in FIG. 3, each of the connection line segments 4 may be connected to four adjacent first signal lines VDD, and the staggered connection line segments may be commonly connected to two adjacent first signal lines VDD.

It should be understood that, in some other embodiments, the connection line segments 4 may also have other arrangement manners and connection manners. For example, at least some of different connection line segments 4 may be connected to different numbers of first signal lines VDD, the connection line segments 4 may be connected to other numbers of first signal lines, and the staggered connection line segments may also be commonly connected to other numbers of first signal lines VDD.

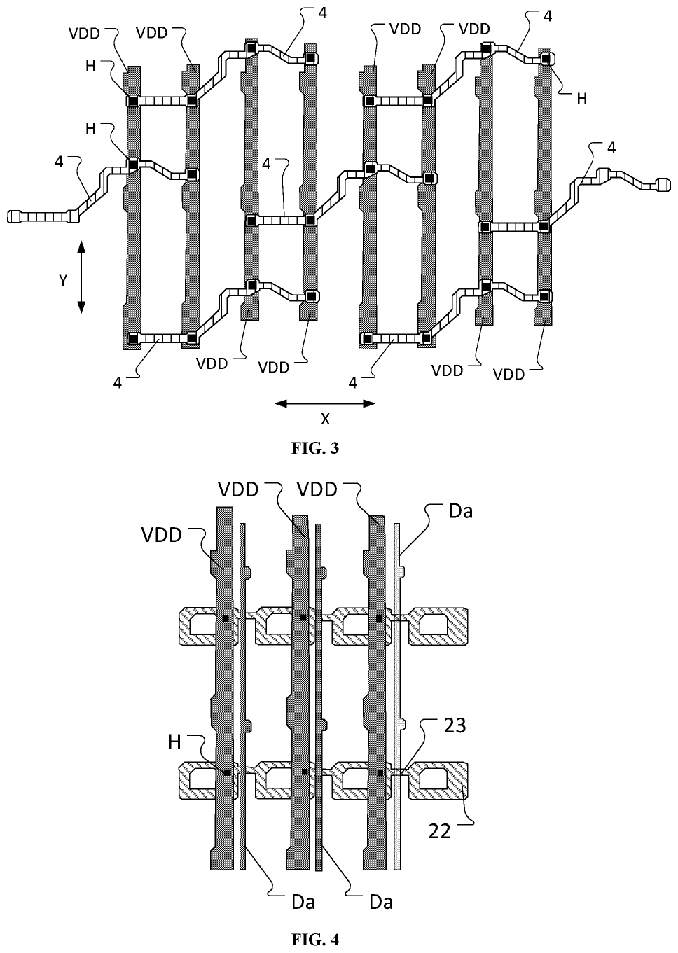

FIG. 4 is a structural layout of a display panel in the related art, where the display panel may include a pixel driving circuit as shown in FIG. 1, and the display panel may further include a base substrate, a second conductive layer and a third conductive layer stacked in sequence. The second conductive layer may include a plurality of conductive parts 22 and connection parts 23 connected between adjacent conductive parts 22, and the third conductive layer may include a power line VDD and a data line Da. The conductive part 22 may be used to form the electrode of the capacitor C, the power line VDD may be used to provide the first power supply terminal in FIG. 1, and the data line Da may be used to provide the data signal terminal in FIG. 1. The power line VDD may be connected to the conductive part 22 through the via hole H to form a grid structure, so as to reduce the voltage drop of the power line. However, as shown in FIG. 4, the orthographic projection of the data line Da on the base substrate intersects with the orthographic projection of the connection part 23 on the base substrate, and a parasitic capacitance is formed between the connection part 23 and the data line Da, thereby increasing the impedance loading (RC loading) of the data line Da, and limiting design of the display panel with a high refresh rate.

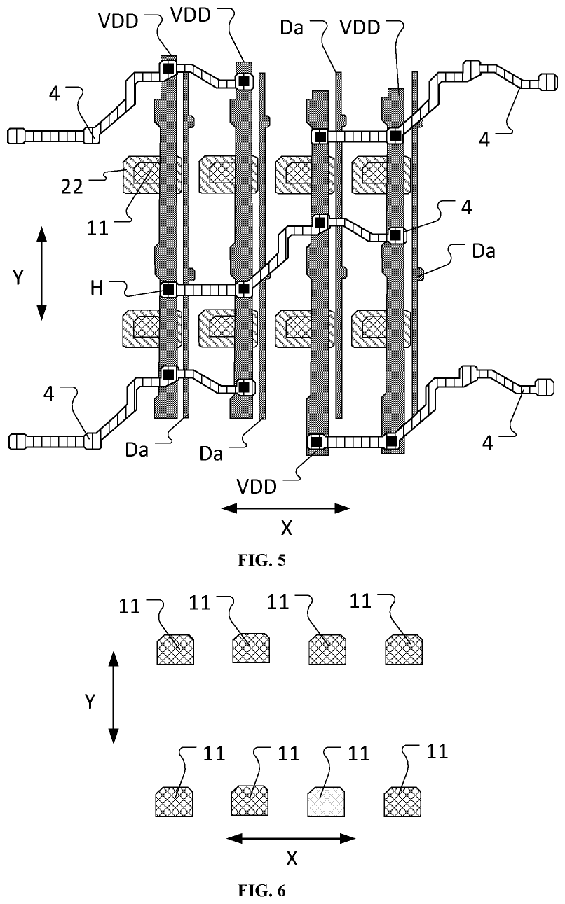

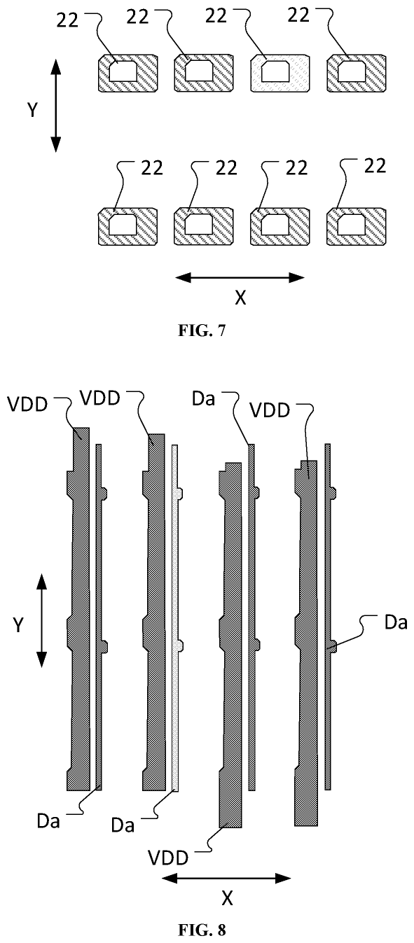

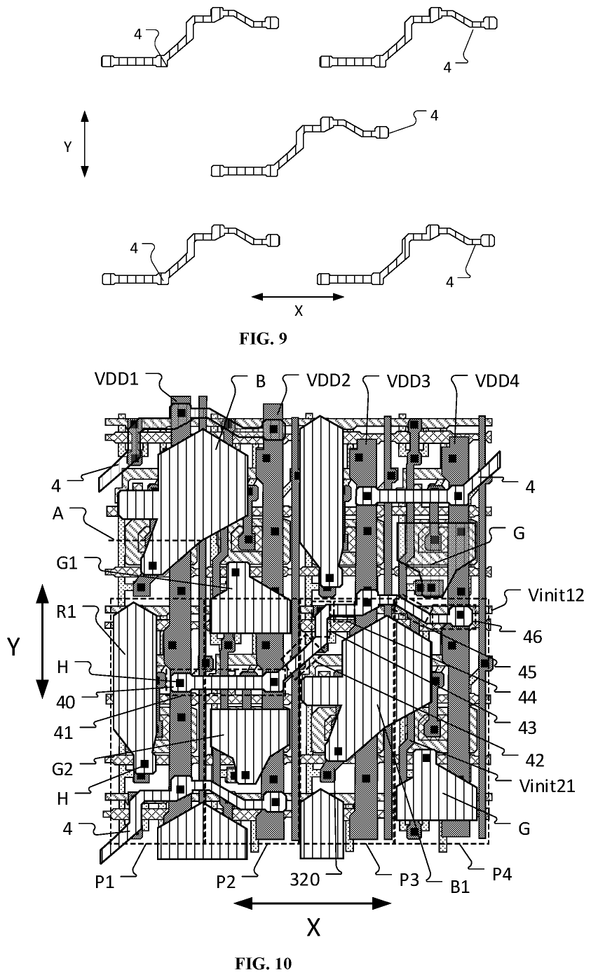

Accordingly, some embodiments also provides another display panel, which may further include a first conductive layer and a second conductive layer, where the base substrate, the first conductive layer, the second conductive layer, the third conductive layer, and the fourth conductive layer are stacked in sequence, and insulating layers may be provided between adjacent layers as described above. As shown in FIG. 5 to FIG. 9, FIG. 5 is a structural layout of a display panel according to some other embodiments of the present disclosure; FIG. 6 is a structural layout of the first conductive layer in FIG. 5; FIG. 7 is a structural layout of the second conductive layer in FIG. 5; FIG. 8 is a structural layout of the third conductive layer in FIG. 5; FIG. 9 is a structural layout of the fourth conductive layer in FIG. 5.

In some embodiments, as shown in FIG. 5 to FIG. 9, the first conductive layer may include a plurality of first conductive parts 11, the orthographic projections of the plurality of first conductive parts 11 on the base substrate may be arranged in an array in the first direction X and the second direction Y, and the first conductive parts 11 may be used to form the gate of the driving transistor T3 and the first electrode of the capacitor C in FIG. 1. The second conductive layer may include a plurality of second conductive parts 22, and the orthographic projections of the plurality of second conductive parts 22 on the base substrate may be arranged in an array in the first direction X and the second direction Y The second conductive parts 22 are provided in a one-to-one correspondence with the first conductive parts 11, the orthographic projections of the second conductive parts 22 on the base substrate at least partially overlap with the orthographic projections of the corresponding first conductive parts 11 on the base substrate, and the second conductive parts 22 are used to form the second electrode of the capacitor C. The third conductive layer may further include the data line Da, which may be used to provide the data signal terminal in FIG. 1. The orthographic projection of the data line Da on the base substrate may extend along the second direction Y, and the orthographic projection of the data line Da on the base substrate may be located between the orthographic projections of two second conductive parts 22 adjacent in the first direction X on the base substrate. Compared with the related art shown in FIG. 4, in the display panel according to some embodiment described herein, the second conductive parts 22 are arranged at intervals in the first direction X, and the data lines Da are arranged between two adjacent second conductive parts 22, the parasitic capacitance formed between the connection part 23 and the data line Da in FIG. 4 an be avoided.

In some embodiments, as shown in FIG. 5, the orthographic projection of the connection line segment 4 on the base substrate may intersect with the orthographic projection of the data line Da on the base substrate, that is, a parasitic capacitance may be generated between the connection line segment 4 and the data line Da. In some embodiments, the display panel may further include a dielectric layer and a planarization layer, where the dielectric layer is located between the second conductive layer and the third conductive layer, the planarization layer is located between the third conductive layer and the fourth conductive layers, and a thickness of the planarization layer may be greater than that of the dielectric layer. Therefore, even if a parasitic capacitance is generated between the connection line segment 4 and the data line Da, since the distance between the connection line segment 4 and the data line Da in FIG. 5 is greater than the distance between the connection part 23 and the data line Da in FIG. 4, the parasitic capacitance on the data line of the display panel shown in FIG. 5 is still smaller than the parasitic capacitance on the data line shown in FIG. 4. In some embodiments, the adjacent first signal lines VDD are connected through the connection line segments 4 located in the fourth conductive layer, the second conductive parts 22 are arranged at intervals in the first direction, and the data line Da is arranged between the adjacent conductive parts 22, the impedance loading (RC loading) of the data line can be reduced while the voltage drop of the first signal line VDD is reduced.

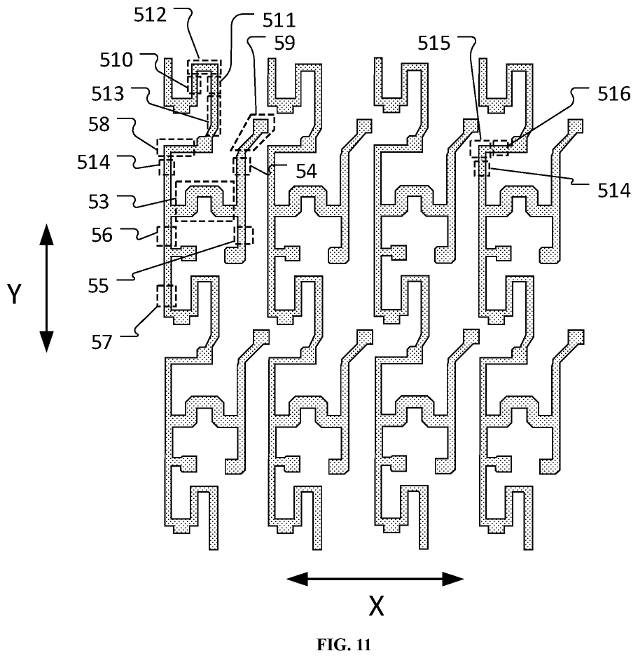

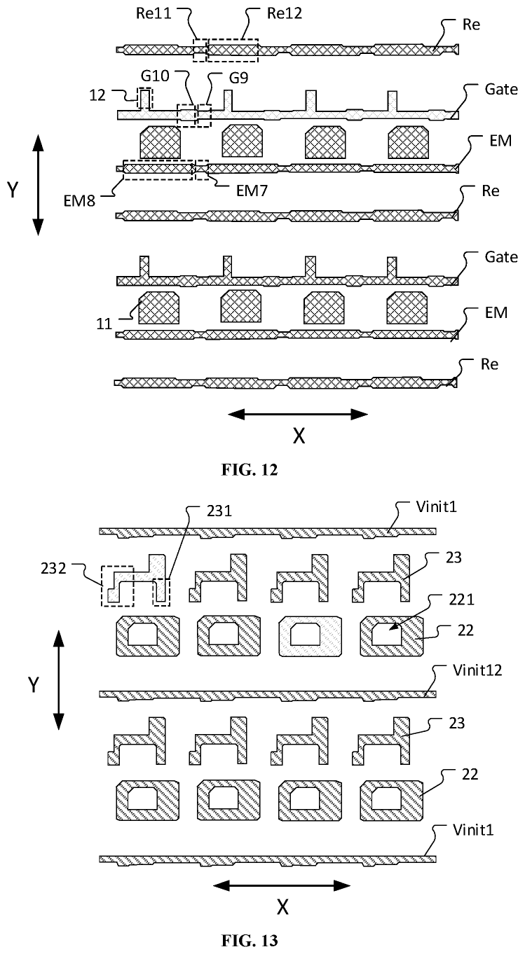

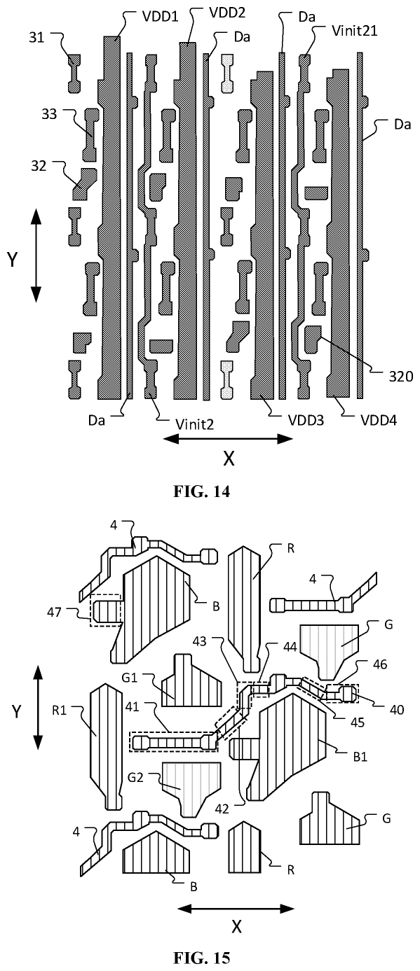

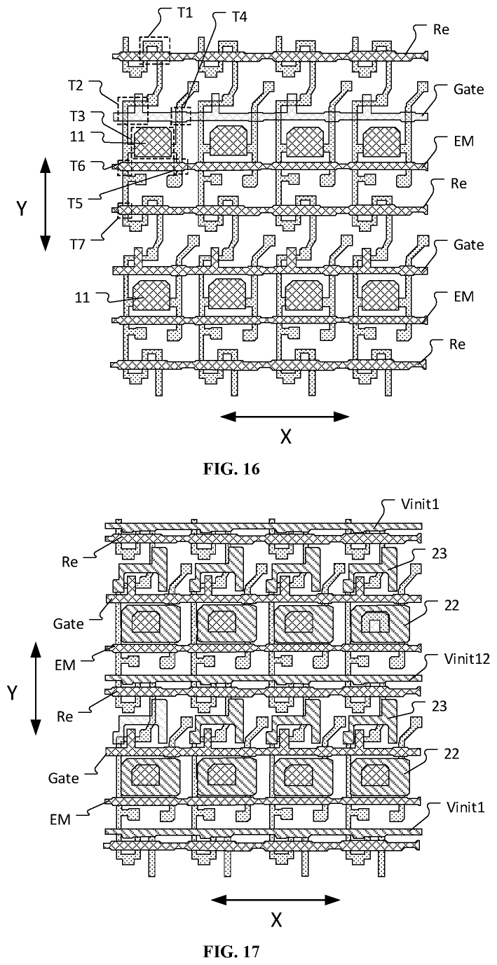

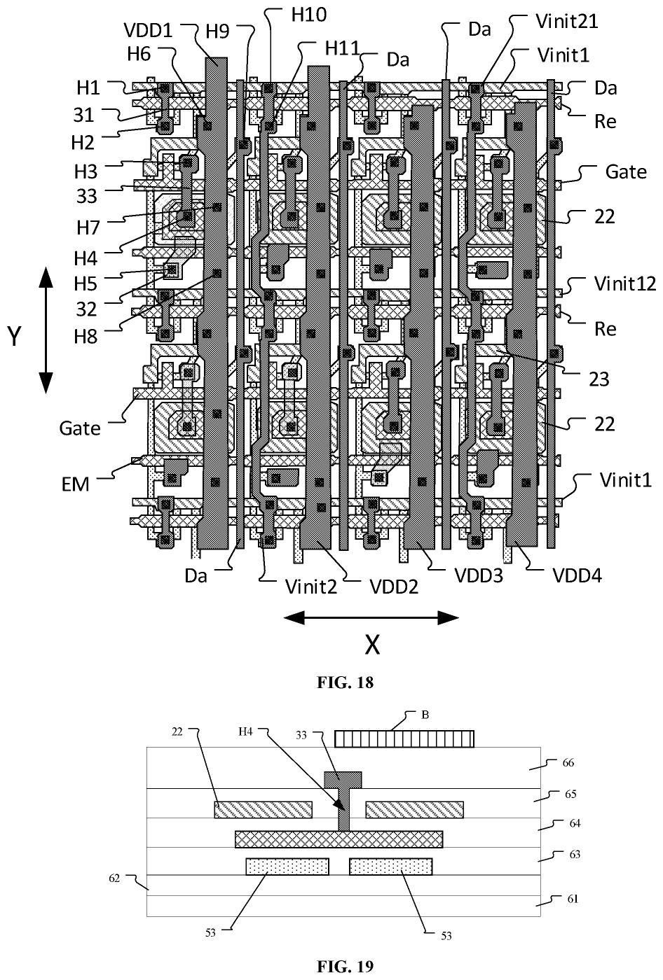

Some embodiments further provides another display panel, which may further include an active layer, where the base substrate, the active layer, the first conductive layer, the second conductive layer, the third conductive layer, and the fourth conductive layer are stacked in sequence, and insulating layers may be provided between adjacent layers as described above. As shown in FIG. 10 to FIG. 18, FIG. 10 is a structural layout of a display panel according to some other embodiments of the present disclosure; FIG. 11 is a structural layout of the active layer in FIG. 10; FIG. 12 is a structural layout of the first conductive layer in FIG. 10; FIG. 13 is a structural layout of the second conductive layer in FIG. 10; FIG. 14 is a structural layout of the third conductive layer in FIG. 10; FIG. 15 is a structural layout of the fourth conductive layer in FIG. 10; FIG. 16 is a structural layout of the active layer and the first conductive layer in FIG. 10; FIG. 17 is a structural layout of the active layer, the first conductive layer, and the second conductive layer in FIG. 10; FIG. 18 is a structural layout of the active layer, the first conductive layer, the second conductive layer, and the third conductive layer in FIG. 10. The first direction X may be the row direction, and the second direction Y may be the column direction. The display panel may include a plurality of pixel driving circuits arranged in rows and columns. As shown in FIG. 10, the plurality of pixel driving circuits may include a first pixel driving circuit P1, a second pixel driving circuit P2, a third pixel driving circuit P3, and a fourth pixel driving circuit P4 arranged adjacently in the row direction.

As shown in FIG. 10, FIG. 11 and FIG. 16, the active layer may include a third active part 53, a fourth active part 54, a fifth active part 55, a sixth active part 56, a seventh active part 57, an eighth active part 58, a ninth active part 59, a tenth active part 510, an eleventh active part 511, a twelfth active part 512, a thirteenth active part 513, a fourteenth active part 514, a fifteenth active part 515, and a sixteenth active part 516. The fourteenth active part 514 is used to form the second channel region of the second transistor T2, the sixteenth active part 516 is used to form the first channel region of the second transistor T2, and the fifteenth active part 515 is connected to between the fourteenth active part 514 and the sixteenth active part 516. The third active part 53 is used to form the channel region of the driving transistor T3, the fourth active part 54 is used to form the channel region of the fourth transistor T4, the fifth active part 55 is used to form the channel region of the fifth transistor T5, the sixth active part 56 is used to form the channel region of the sixth transistor T6, the seventh active part 57 is used to form the channel region of the seventh transistor T7, the tenth active part 510 is used to form the first channel region of the first transistor, the eleventh active part 511 is used to form the second channel region of the first transistor, the twelfth active part 512 is connected between the eleventh active part 511 and the tenth active part 510, and the ninth active part 59 is connected to one end of the fourth active part 54 away from the third active part 53. The thirteenth active part 513 is connected between the eleventh active part 511 and the eighth active part 58, and the orthographic projection of the thirteenth active part 513 on the base substrate extends along the second direction. The active layer may be formed of polycrystalline silicon, and the transistors formed on the active layer may be low temperature polycrystalline silicon transistors.

As shown in FIG. 10, FIG. 12 and FIG. 16, the first conductive layer may include a first conductive part 11, a reset signal line Re, a gate driving signal line Gate, an enable signal line EM, and a protrusion part 12. The first conductive part 1 is used to form the gate of the driving transistor T3. The orthographic projection of the reset signal line Re on the base substrate, the orthographic projection of the gate driving signal line Gate on the base substrate, and the orthographic projection of the enable signal line EM on the base substrate may all extend along the first direction X. The orthographic projection of a partial structure of the reset signal line Re on the base substrate covers the orthographic projections of the tenth active part 510 and the eleventh active part 511 in the pixel driving circuit of the same row on the base substrate, and this partial structure of the reset signal line Re is used to form the gate of the first transistor in the pixel driving circuit of this row. The orthographic projection of the other partial structure of the reset signal line Re on the base substrate covers the orthographic projection of the seventh active part 57 in the pixel driving circuit of a previous row on the base substrate, and the other partial structure thereof may be used to form the gate of the seventh transistor in the pixel driving circuit of the previous row. The orthographic projection of the gate driving signal line Gate on the base substrate covers the orthographic projections of the fourth active part 54 and the second active part 52 on the base substrate, a partial structure of the gate driving signal line Gate is used to form the gate of the four transistor, and the other partial structure of the gate driving signal line Gate is used to form the second gate of the second transistor. The protrusion part 12 is connected to the gate driving signal line Gate, the orthographic projection of the protrusion part 12 on the base substrate covers the orthographic projection of the sixteenth active part 516 on the base substrate, and a partial structure of the protrusion part 12 is used to form the first gate of the second transistor. The orthographic projection of the enable signal line EM on the base substrate covers the orthographic projections of the fifth active part 55 and the sixth active part 56 on the base substrate, a partial structure of the enable signal line EM is used to form the gate of the fifth transistor T5, and the other partial structure of the enable signal line EM is used to form the gate of the sixth transistor T6. As shown in FIG. 12, the enable signal line EM may include a seventh extension part EM7 and an eighth extension part EM8 which are alternately connected in sequence, and in the second direction Y, a size of the orthographic projection of the seventh extension part EM7 on the base substrate is smaller than a size of the orthographic projection of the eighth extension part EM8 on the base substrate. The gate driving signal line Gate may include a ninth extension part G9 and a tenth extension part G10 which are alternately connected in sequence, and in the second direction Y, a size of the orthographic projection of the ninth extension part G9 on the base substrate is smaller than a size of the orthographic projection of the tenth extension G10 on the base substrate. The reset signal line Re may include an eleventh extension part Re11 and a twelfth extension part Re12 that are alternately connected in sequence, and in the second direction Y, a size of the orthographic projection of the eleventh extension part Re11 on the base substrate is smaller than a size of the orthographic projection of the twelfth extension Re12 on the base substrate. Moreover, in the display panel, conductive treatment may be performed on the active layer by using the first conductive layer as a mask, that is, the active layer covered by the first conductive layer may form the channel region of the transistor, and the active layer not covered by the first conductive layer may form conductive structures.

As shown in FIG. 10, FIG. 13 and FIG. 17, the second conductive layer may include a plurality of first initial signal lines Vinit1, a second conductive part 22 and a third conductive part 23. The orthographic projections of the plurality of first initial signal lines Vinit1 on the base substrate extend along the first direction X, and are spaced in the second direction Y Each first initial signal line Vinit1 is provided corresponding to a row of pixel driving circuits. The first initial signal line Vinit1 may be used to provide the initial signal terminal for the first transistor T1 in the corresponding pixel driving circuit, and the first initial signal line Vinit1 may also be used to provide the initial signal terminal to the seventh transistor in the pixel driving circuit of the upper row. In some embodiments, the plurality of first initial signal lines Vinit1 include a second initial signal sub-line Vinit12 corresponding to the fourth pixel driving circuit. The orthographic projection of the second conductive part 22 on the base substrate at least partially overlaps with the orthographic projection of the first conductive part 11 on the base substrate. The second conductive part 22 is used to form the second electrode of the capacitor C. The second conductive part 22 may also be provided with an opening 211, and the opening 211 exposes a part of the first conductive part 11. The third conductive part includes a first conductive sub-part 231 and a second conductive sub-part 232, and the orthographic projection of the first conductive sub-part 231 on the base substrate may extend along the second direction Y.

As shown in FIG. 10, FIG. 14 and FIG. 18, the third conductive layer may include a plurality of first signal lines, and the plurality of first signal lines may include a first signal sub-line VDD1, a second signal sub-line VDD2, a third signal sub-line VDD3, and a fourth signal sub-line VDD4. The orthographic projections of the plurality of first signal lines on the base substrate are spaced apart in the first direction X and extend along the second direction Y The plurality of first signal lines are provided in a one-to-one correspondence with multiple columns of pixel driving circuits, and the first signal lines may be used to provide a first power supply terminal to the corresponding pixel driving circuits. In some embodiments, the first signal sub-line VDD1 is provided corresponding to the first pixel driving circuit, the second signal sub-line VDD2 is provided corresponding to the second pixel driving circuit, the third signal sub-line VDD3 is provided corresponding to the third pixel driving circuit, and the fourth signal sub-line VDD4 is provided corresponding to the fourth pixel driving circuit. The third conductive layer may further include a plurality of data lines Da, and the orthographic projections of the plurality of data lines Da on the base substrate are spaced apart in the first direction X and extend along the second direction Y The plurality of data lines Da are provided in a one-to-one correspondence with multiple columns of pixels driving circuits, and the data lines Da may be used to provide data signal terminals to the corresponding pixel driving circuits. The third conductive layer may further include a plurality of second initial signal lines Vinit2, and the orthographic projections of the plurality of second initial signal lines Vinit2 on the base substrate are spaced apart in the first direction X and extend along the second direction Y The plurality of second initial signal lines Vinit2 may be provided in a one-to-one correspondence with some columns of pixel driving circuit. For example, a second initial signal line Vinit2 may be provided corresponding to every other column of pixel driving circuits, that is, one second initial signal line Vinit2 may be provided for every two columns of pixel driving circuits. The plurality of second initial signal lines Vinit2 may include a first initial signal sub-line Vinit21 corresponding to the fourth pixel driving circuit, and the orthographic projection of the first initial signal sub-line Vinit2l on the base substrate is located within the orthographic projection of a pixel driving circuit column, where the fourth pixel driving circuit is located, on the base substrate.

As shown in FIG. 10, FIG. 14 and FIG. 18, the third conductive layer further includes a first connection part 31, a second connection part 32 and a third connection part 33. The data line Da may be connected to the ninth active part 59 through the via hole H9 to connect the first electrode of the fourth transistor and the data signal terminal. The first signal sub-line VDD1 is connected to the active layer on one side of the fifth active part 55 through the via hole H8 to connect the first electrode of the fifth transistor and the first power supply terminal. The first signal sub-line VDD1 is also connected to the second conductive part through the via hole H7 to connect the second electrode of the capacitor C and the first power supply terminal. The first signal sub-line VDD1 is also connected to the third conductive part 23 through the via hole H6. The orthographic projection of the first conductive sub-part 231 on the base substrate may be located between the orthographic projection of the data line Da on the base substrate and the orthographic projection of the thirteenth active part 513 on the base substrate. The first sub-conducting part 231 may be used to shield the noise influence of the data line Da on the thirteenth active part 513, thereby improving the voltage stability at the node N in FIG. 1 during the light emission stage. The orthographic projection of the second conductive sub-part 232 on the base substrate may at least partially overlap with the orthographic projection of the fifteenth active part 515 on the base substrate, and the second conductive sub-part 232 may serve as voltage stabilizer of the fifteenth active part 515, thereby reducing the leakage current from the fifteenth active part 515 to the source and drain of the second transistor. In some other embodiments, the third conductive part 23 may also be connected to other stable voltage sources, for example, the third conductive part 23 may be connected to the second initial signal line. The first connection part 31 may be connected to the first initial signal line Vinit1 through the via hole H1, and may be connected to the active layer on the side of the tenth active part 510 away from the twelfth active part 512 through the via hole H2, so as to connect the second electrode of the first transistor in the same row and the initial signal terminal, and connect the first electrode of the seventh transistor in the upper row and the initial signal terminal. The second connection part 32 may be connected to the active layer between the sixth active part 56 and the seventh active part 57 through the via hole H5 to connect the second electrode of the sixth transistor. The second connection part 32 may be connected to an electrode of the light-emitting unit. The third connection part 33 may be connected to the thirteenth active part 513 through the via hole H3, and connected to the first conductive part 11 through the via hole H4, so as to connect the gate of the driving transistor and the second electrode of the second transistor. The orthographic projection of the via hole H4 on the base substrate may be located within that of the opening 221 on the base substrate, so as to insulate the conductive structure in the via hole H4 from the second conductive part 22. The second initial signal line Vinit2 may be connected to the first initial signal line Vinit1 through the via hole H10, and the first initial signal line Vinit1 and the second initial signal line Vinit2 may form a grid structure, thereby reducing the voltage difference between the initial signal terminals at different positions of the display panel. As shown in FIG. 18, the second initial signal line Vinit2 may be also connected to the active layer on the side of the tenth active part 510 away from the twelfth active part 512 through H11, so as to realize the bridging function of the first connection part 31. Therefore, the pixel driving circuit column in which the second initial signal line Vinit2 is provided may not be provided with the first connection part 31. It should be noted that the orthographic projection of a pixel driving circuit column on the substrate may be understood as the orthographic projection formed by the combination of the orthographic projections of all pixel driving circuits in the pixel driving circuit column on the base substrate. The orthographic projection of a pixel driving circuit row on the substrate may be understood as the orthographic projection formed by the combination of the orthographic projections of all pixel driving circuits in the pixel driving circuit row on the base substrate. The orthographic projection of a pixel driving circuit on the base substrate may be understood as a circumscribed rectangle in which all devices in the pixel driving circuit are orthographically projected on the base substrate, where a length direction of the circumscribed rectangle is the second direction, and a width direction thereof is the first direction.

As shown in FIG. 10, FIG. 14 and FIG. 18, the orthographic projection of the ninth extension part G9 on the base substrate intersects with the orthographic projection of the data line Da on the base substrate; the orthographic projection of the eleventh extension part Re11 on the base substrate intersects with the orthographic projection of the data line on the base substrate; and the orthographic projection of the seventh extension EM7 on the base substrate intersects with the orthographic projections of the data line on the base substrate. In this arrangement, the overlapping area between the data line Da and the enable signal line EM, the gate driving signal line Gate, and the reset signal line Re can be reduced, thereby reducing the parasitic capacitance of the data line.

As shown in FIG. 10 and FIG. 15, the fourth conductive layer may include a plurality of connection line segments 4 arranged in rows and columns, multiple rows of the connection line segments may be provided in a one-to-one correspondence with multiple rows of the pixel driving circuits, and the orthographic projection of at least a partial structure of the connection line segments 4 on the base substrate is located within the orthographic projection of the corresponding pixel driving circuit row on the base substrate. As shown in FIG. 10 and FIG. 15, each connection line segment 4 may be provided corresponding to four adjacent pixel driving circuits. The plurality of connection line segments 4 include a first connection line segment 40, which is provided corresponding to the first pixel driving circuit P1, a second pixel driving circuit P2, a third pixel driving circuit P3, and a fourth pixel driving circuit P4, and the first connection line segment 40 is respectively connected to the first signal sub-line VDD1, the second signal sub-line VDD2, the third signal sub-line VDD3 and the fourth signal sub-line VDD4 through a via hole. The first connection line segment 40 may include a first extension part 41, a second extension part 42, a third extension part 43, a fourth extension part 44, a fifth extension part 45, and a sixth extension part 46 connected in sequence. The orthographic projection of the first extension part 41 on the base substrate extends along the first direction X, a first end of the first extension part 41 is connected to the first signal sub-line VDD1 through a via hole, a second end of the first extension 41 is connected to the second signal sub-line VDD2 through a via hole, and the orthographic projection of the first extension part 41 on the base substrate covers the orthographic projection of the eighth active part 58 in the second driving circuit P2 on the base substrate. Through this arrangement, not only the influence of the first extension part 41 on the light transmittance of the display panel can be reduced, but also the sixteenth active part can be shielded from light, thereby reducing the change of the output characteristic of the second transistor due to illumination. The orthographic projection of the second extension part 42 on the base substrate at least partially overlaps with the orthographic projection of the ninth active part 59 in the second pixel driving circuit P2 on the base substrate, and an included angle between the orthographic projection of the second extension part 42 on the base substrate and the orthographic projection of the first extension part 41 on the base substrate is an obtuse angle. The orthographic projection of the third extension part 43 on the base substrate extends along the second direction Y, and the orthographic projection of the third extension part 43 on the base substrate at least partially overlaps with the orthographic projections of the first connection part 31 in the third driving circuit P3 on the base substrate. The orthographic projection of the fourth extension part 44 on the base substrate extends along the first direction X, and the orthographic projection of the fourth extension part 44 on the base substrate at least partially overlaps with the orthographic projection of the twelfth active part 512 in the third driving circuit P3 on the base substrate. The orthographic projection of the fifth extension part 45 on the base substrate at least partially overlaps with the orthographic projection of the first initial signal sub-line Vinit21 on the base substrate. The orthographic projection of the sixth extension part 46 on the base substrate at least partially overlaps with the orthographic projection of the second initial signal sub-line Vinit12 on the base substrate. Through this arrangement, the connection line segment can be made to overlap with its underlying structure as much as possible on the premise of fully reserving the layout space of the electrode parts, thereby reducing the influence of the connection line segment on the light transmittance of the display panel.

As shown in FIG. 10 and FIG. 15, the fourth conductive layer further includes a plurality of electrode parts arranged in rows and columns, and the electrode parts are used to form electrodes of the light-emitting units. The plurality of electrode parts may include a red (R) electrode part R, a green (G) electrode part G, and a blue (B) electrode part B, where the R electrode part is an electrode part of a red light-emitting unit, the G electrode part is an electrode part of a green light-emitting unit, and the B electrode part is an electrode part of a blue light-emitting unit. The R electrode parts R, G electrode parts G, and B electrode parts B are alternately arranged in sequence along the same electrode row. In the same electrode row, two G electrode parts arranged along the column direction are provided between an R electrode part and a B electrode part. In adjacent electrode rows, electrode parts of the same color are located in different columns, and in two electrode rows separated by one electrode row therebetween, electrode parts of the same color are located in the same column. As shown in FIG. 10 and FIG. 15, multiple rows of electrode parts include a first electrode row, and the first electrode row includes a first R electrode part R1, a first G electrode part G1, a second G electrode part G2, and a first B electrode part B1 sequentially arranged in the row direction, where the first G electrode part G1 and the second G electrode part G2 are located in the same electrode column. The first R electrode part R1 forms the R electrode part, the first G electrode part G1 and the second G electrode part G2 forms the G electrode part, and the first B electrode part B1 forms the B electrode part. The plurality of second connection parts 32 include a first connection sub-part 320 for connecting the first B-electrode part B1. The orthographic projection of the first extension part 41 on the base substrate may be located between the orthographic projection of the first G electrode part G1 on the base substrate and the orthographic projection of the second G electrode part G2 on the base substrate. The orthographic projection of the fourth extension part 44 on the base substrate, the orthographic projection of the fifth extension part 45 on the base substrate, and the orthographic projection of the sixth extension part 46 on the base substrate may be located on the side of the orthographic projection of the first B electrode part B1 on the base substrate away from the orthographic projection of the first connection sub-part 320 on the base substrate. It should be noted that other connection line segments may have the same arrangement and connection manner as the first connection line segment.

As shown in FIG. 10 and FIG. 15, the fourth conductive layer may further include a conductive part 47 connected to the B electrode part, and the orthographic projection of the conductive part 47 on the base substrate may cover the orthographic projections of the fourteenth active part 514 and the sixteenth active part 516 on the base substrate, so as to shield the channel region of the second transistor from light.

As shown in FIG. 19, it is a partial cross-sectional view taken along dotted line A in FIG. 10. The display panel may further include a buffer layer 62, a first insulating layer 63, and a second insulating layer 64, where the base substrate 61, the buffer layer 62, the active layer, the first insulating layer 63, the first conductive layer, the second insulating layer 64, the second conductive layer, the dielectric layer 65, the third conductive layer, the planarization layer 66, and the fourth conductive layer are stacked in sequence. The first insulating layer 63 and the second insulating layer 64 may be silicon oxide layers, the dielectric layer 65 may be a silicon nitride layer, and the material of the planarization layer 66 may be an organic material, such as polyimide (PI), polyethylene terephthalate (PET), polyethylene naphthalate (PEN), silicon-glass bonded structure (SOG) and the like. The base substrate 61 may include a glass substrate, a barrier layer, and a polyimide layer stacked in sequence, and the barrier layer may be made of an inorganic material. The material of the first conductive layer and the second conductive layer may be any one or an alloy of molybdenum, aluminum, copper, titanium, and niobium, or may be a molybdenum/titanium alloy or a laminate layer thereof. The material of the third conductive layer may include metal materials, such as one or an alloy of molybdenum, aluminum, copper, titanium, and niobium, or may be a molybdenum/titanium alloy or a laminate layer thereof, or may be a laminate layer of titanium/aluminum/titanium. The material of the fourth conductive layer may be indium tin oxide.

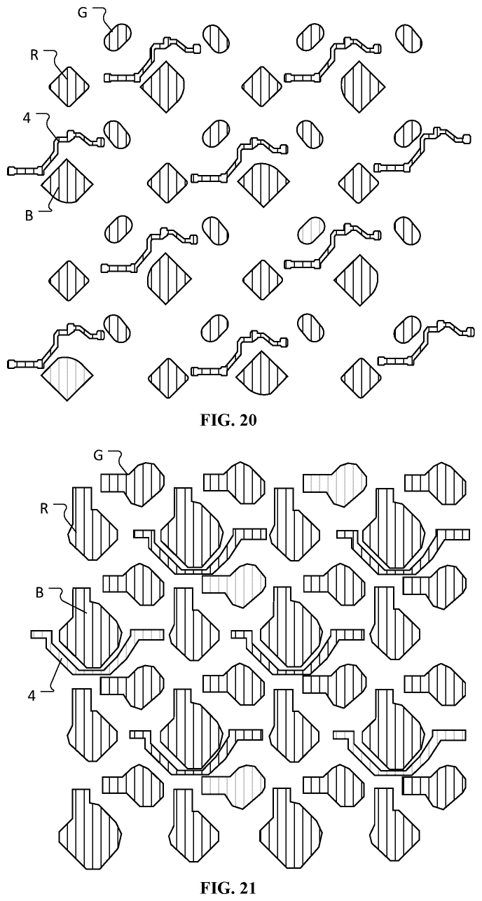

It should be understood that, in some other embodiments, the electrode parts in the display panel may also have other arrangement manners and shapes, and the connection line segments may also have other arrangement manners and shapes. For example, as shown in FIG. 20, which is a structural layout of a fourth conductive layer in a display panel according to some other embodiments of the present disclosure, the fourth conductive layer of the display panel may include an electrode part R of a red light-emitting unit, an electrode part B of a blue light-emitting unit, an electrode part G of a green light-emitting unit, and a connection line segment 4. Herein, a plurality of electrode parts G are arranged along the same electrode row at intervals, and a plurality of electrode parts R and B are arranged alternately along the same electrode row. The electrode row where the electrode parts G are located and the electrode rows where the electrode parts R and the electrode parts B are located are alternately arranged in the column direction. A plurality of electrode parts G are arranged along the same electrode column at intervals, and a plurality of electrode parts R and B are arranged alternately along the same electrode column. The electrode column where the electrode parts G are located and the electrode columns where the electrode parts R and the electrode parts B are located are alternately arranged in the row direction. The staggered connection line segments 4 may be commonly connected to one first signal line. For another example, as shown in FIG. 21, which is a structural layout of a fourth conductive layer in a display panel according to some other embodiments of the present disclosure, the electrode parts shown in FIG. 21 and the electrode parts shown in FIG. 20 have the same arrangement manner and different shapes. The staggered connection line segments 4 may also be commonly connected to one first signal line.

Some embodiments further provide a display device, which includes the display panel as described above. The display device may be a display device of, for example, a mobile phone, a tablet computer, a TV set and the like.

Other embodiments of the present disclosure will readily suggest themselves to those skilled in the art upon consideration of the specification and practice of what is disclosed herein. This application is intended to cover any variations, uses, or adaptations of the present disclosure that follow the general principles of the present disclosure and include common knowledge or techniques in the technical field not disclosed by the present disclosure. The specification and examples are to be regarded as exemplary only, with the actual scope and spirit of the disclosure being indicated by the claims.

It is to be understood that the present disclosure is not limited to the precise structures described above and illustrated in the accompanying drawings, and that various modifications and changes may be made without departing from the scope thereof. The scope of the present disclosure is limited only by the appended claims.

1. A display panel, comprising:
a base substrate;
a third conductive layer located on one side of the base substrate, wherein the third conductive layer comprises first signal lines, orthographic projections of the first signal lines on the base substrate are spaced apart in a first direction and extend along a second direction, and the first direction intersects with the second direction; and
a fourth conductive layer located on one side of the third conductive layer away from the base substrate, wherein the fourth conductive layer comprises connection line segments, orthographic projections of the connection line segments on the base substrate extend along the first direction, and a same one of the connection line segments is connected to multiple ones of the first signal lines through via holes, respectively.

2. The display panel according to claim 1, wherein the first signal line is a power line.

3. The display panel according to claim 1, wherein the display panel further comprises pixel driving circuits arranged in the first direction and the second direction, the pixel driving circuit comprises a driving transistor, a capacitor and a fourth transistor, a first electrode of the capacitor is connected to a gate of the driving transistor, a second electrode of the capacitor is connected to a power line, a second electrode of the fourth transistor is connected to a first electrode of the driving transistor, and a first electrode of the fourth transistor is connected to a data line;
the display panel further comprises:
a first conductive layer located between the base substrate and the third conductive layer, wherein the first conductive layer comprises first conductive parts, orthographic projections of the first conductive parts on the base substrate are spaced apart in the first direction, and the first conductive parts are used to form the gate of the driving transistor and the first electrode of the capacitor; and
a second conductive layer located between the first conductive layer and the third conductive layer, wherein the second conductive layer comprises second conductive parts, orthographic projections of the second conductive parts on the base substrate are spaced apart in the first direction, the second conductive parts are provided in a one-to-one correspondence with the first conductive parts, the orthographic projections of the second conductive parts on the base substrate at least partially overlaps with orthographic projections of corresponding first conductive parts on the base substrate, and the second conductive parts are used to form the second electrode of the capacitor;
the third conductive layer further comprises:
the data line, wherein an orthographic projection of the data line on the base substrate extends along the second direction, and the orthographic projection of the data line on the base substrate is located between orthographic projections of two second conductive parts adjacent in the first direction on the base substrate.

4. The display panel according to claim 3, wherein the orthographic projection of the data line on the base substrate intersects with the orthographic projections of the connection line segments on the base substrate; and
the display panel further comprises:
a dielectric layer, located between the second conductive layer and the third conductive layer; and
a planarization layer, located between the third conductive layer and the fourth conductive layer, wherein a thickness of the planarization layer is greater than a thickness of the dielectric layer.

5. The display panel according to claim 1, wherein the first direction is a row direction, the second direction is a column direction, and the fourth conductive layer comprises the connection line segments arranged in the row direction and the column direction;
the connection line segments located in a same row are spaced apart in the row direction, and adjacent connection line segments in the same row are connected to different ones of the first signal lines;
the connection line segments located in a same column are spaced apart in the column direction, and the connection line segments in the same column are connected to a same group of the first signal lines;
the connection line segments of adjacent rows and adjacent columns are staggered in the first direction, and the staggered connection line segments are commonly connected to at least one of the first signal lines.

6. The display panel according to claim 5, wherein each connection line segment is connected to four adjacent first signal lines, and the staggered connection line segments are commonly connected to two adjacent first signal lines.

7. The display panel according to claim 5, wherein the display panel comprises pixel driving circuits arranged in rows and columns;
the first signal lines are provided in a one-to-one correspondence with multiple columns of the pixel driving circuits, and the pixel driving circuits are connected to corresponding first signal lines; and
multiple rows of the connection line segments are provided in a one-to-one correspondence with multiple rows of the pixel driving circuits, and an orthographic projection of at least a partial structure of the connection line segments on the base substrate is located within an orthographic projection of a corresponding row of the pixel driving circuits on the base substrate.

8. The display panel according to claim 1, wherein the first direction is a row direction, the second direction is a column direction, the display panel comprises pixel driving circuits arranged in rows and columns, the first signal lines are provided in a one-to-one correspondence with multiple columns of the pixel driving circuits, and the pixel driving circuits are connected to corresponding first signal lines;
the pixel driving circuits comprise a first pixel driving circuit, a second pixel driving circuit, a third pixel driving circuit and a fourth pixel driving circuit arranged adjacently in sequence along the first direction;
the first signal lines comprise a first signal sub-line, a second signal sub-line, a third signal sub-line and a fourth signal sub-line, wherein the first signal sub-line is provided corresponding to the first pixel driving circuit, the second signal sub-line is provided corresponding to the second pixel driving circuit, the third signal sub-line is provided corresponding to the third pixel driving circuit, and the fourth signal sub-line is provided corresponding to the fourth pixel driving circuit; and
the connection line segments comprise a first connection line segment, wherein the first connection line segment is respectively connected to the first signal sub-line, the second signal sub-line, the third signal sub-line and the fourth signal sub-line through via holes, and an orthographic projection of the first connection line segment on the base substrate at least partially intersects with an orthographic projection of the second pixel driving circuit on the base substrate.

9. The display panel according to claim 8, wherein the pixel driving circuit comprises a driving transistor and a second transistor, a first electrode of the second transistor is connected to a first electrode of the driving transistor, and a second electrode of the second transistor is connected to a gate of the driving transistor;
the display panel further comprises:
an active layer located between the base substrate and the third conductive layer, wherein the active layer comprises an eighth active part, an orthographic projection of the eighth active part on the base substrate extends along the first direction, and at least a partial structure of the eighth active part is used to form a first channel region of the second transistor; and
the first connection line segment comprises:
a first extension part, wherein an orthographic projection of the first extension part on the base substrate extends along the first direction, a first end of the first extension part is connected to the first signal sub-line through a via hole, a second end of the first extension part is connected to the second signal sub-line through a via hole, and the orthographic projection of the first extension part on the base substrate covers an orthographic projection of the eighth active part in the second pixel driving circuit on the base substrate.

10. The display panel according to claim 8, wherein the pixel driving circuit further comprises a driving transistor and a fourth transistor, a second electrode of the fourth transistor is connected to a second electrode of the driving transistor, and a first electrode of the fourth transistor is connected to a data line;
the display panel further comprises an active layer located between the base substrate and the third conductive layer, wherein the active layer further comprises:
a fourth active part used to form a channel region of the fourth transistor; and
a ninth active part connected between the fourth active part and the data line;
the first connection line segment further comprises:
a second extension part, wherein an orthographic projection of the second extension part on the base substrate at least partially overlaps with an orthographic projection of the ninth active part in the second pixel driving circuit on the base substrate.

11. The display panel according to claim 8, wherein the pixel driving circuit further comprises a driving transistor and a first transistor, a first electrode of the first transistor is connected to a gate of the driving transistor, and a second electrode of the first transistor is connected to a first initial signal line;
the third conductive layer further comprises:
a first connection part, wherein the first connection part is connected between the first initial signal line and the second electrode of the first transistor, and an orthographic projection of the first connection part on the base substrate extends along the second direction;
the first connection line segment comprises:
a third extension part, wherein an orthographic projection of the third extension part on the base substrate extends along the second direction, and the orthographic projection of the third extension part on the base substrate at least partially overlaps with an orthographic projection of the first connection part in the third pixel driving circuit on the base substrate.

12. The display panel according to claim 8, wherein the pixel driving circuit further comprises a driving transistor and a first transistor, a first electrode of the first transistor is connected to a gate of the driving transistor, and a second electrode of the first transistor is connected to a first initial signal line;
the display panel further comprises:
an active layer located between the base substrate and the third conductive layer, wherein the active layer comprises a tenth active part, an eleventh active part, and a twelfth active part, the tenth active part is used to form a first channel region of the first transistor, the eleventh active part is used to form a second channel region of the first transistor, the twelfth active part is connected between the tenth active part and the eleventh active part, and an orthographic projection of the twelfth active part on the base substrate extends along the first direction;
the first connection line segment comprises:
a fourth extension part, wherein an orthographic projection of the fourth extension part on the base substrate extends along the first direction, and the orthographic projection of the fourth extension part on the base substrate at least partially overlaps with an orthographic projection of the twelfth active part in the third pixel driving circuit on the base substrate.

13. The display panel according to claim 8, wherein the pixel driving circuit further comprises a driving transistor and a first transistor, a first electrode of the first transistor is connected to a gate of the driving transistor, and a second electrode of the first transistor is connected to a first initial signal line;
the display panel further comprises:
a second conductive layer located between the base substrate and the third conductive layer, wherein the second conductive layer comprises first initial signal lines, orthographic projections of the first initial signal lines on the base substrate extend along the first direction and are spaced apart in the second direction, the first initial signal lines are provided in a one-to-one correspondence with multiple rows of the pixel driving circuits, and the first transistors in the pixel driving circuits are connected to corresponding first initial signal lines;
the third conductive layer comprises:
second initial signal lines, wherein orthographic projections of the second initial signal lines on the base substrate extend along the second direction and are spaced apart in the first direction, and the first initial signal lines are connected to the second initial signal lines intersected therewith through via holes.

14. The display panel according to claim 13, wherein the second initial signal lines comprise a first initial signal sub-line, and an orthographic projection of the first initial signal sub-line on the base substrate at least partially overlaps with an orthographic projection of the fourth pixel driving circuit on the base substrate;
the first initial signal lines comprise a second initial signal sub-line corresponding to the fourth pixel driving circuit;
the first connection line segment comprises:
a fifth extension part, wherein an orthographic projection of the fifth extension part on the base substrate at least partially overlaps with the orthographic projection of the first initial signal sub-line on the base substrate; and
a sixth extension part, wherein an orthographic projection of the sixth extension part on the base substrate at least partially overlaps with an orthographic projection of the second initial signal sub-line on the base substrate.

15. The display panel according to claim 8, wherein the pixel driving circuit comprises a driving transistor, a first transistor, a second transistor, and a fourth transistor, a first electrode of the first transistor is connected to a gate of the driving transistor, a second electrode of the first transistor is connected to the first initial signal line, a first electrode of the second transistor is connected to a first electrode of the driving transistor, a second electrode of the second transistor is connected to the gate of the driving transistor, a second electrode of the fourth transistor is connected to a second electrode of the driving transistor, and a first electrode of the fourth transistor is connected to a data line;
the display panel further comprises:
a first conductive layer located between the base substrate and the third conductive layer;
a second conductive layer located between the first conductive layer and the third conductive layer, wherein the second conductive layer comprises first initial signal lines, orthographic projections of the first initial signal lines on the base substrate extend along the first direction and are spaced apart in the second direction, the first initial signal lines are provided in a one-to-one correspondence with multiple rows of the pixel driving circuits, and the first transistors in the pixel driving circuits are connected to corresponding first initial signal lines; and
an active layer located between the base substrate and the first conductive layer, wherein the active layer comprises a fourth active part, an eighth active part, a ninth active part, a tenth active part, an eleventh active part and a twelfth active part; wherein the fourth active part is used to form a channel region of the fourth transistor, the ninth active part is connected between the fourth active part and the data line, an orthographic projection of the eighth active part on the base substrate extends along the first direction, at least a partial structure of the eighth active part is used to form a first channel region of the second transistor, the tenth active part is used to form a first channel region of the first transistor, the eleventh active part is used to form a second channel region of the first transistor, the twelfth active part is connected between the tenth active part and the eleventh active part, and an orthographic projection of the twelfth active part on the base substrate extends along the first direction;
the third conductive layer comprises:
second initial signal lines, wherein orthographic projections of the second initial signal lines on the base substrate extend along the second direction and are spaced in the first direction, and the second initial signal lines are connected to the first initial signal lines intersecting therewith through via holes; and
a first connection part, wherein the first connection part is connected between the initial signal line and the second electrode of the first transistor, and an orthographic projection of the first connection part on the base substrate extends along the second direction;
the first connection line segment comprises a first extension part, a second extension part, a third extension part, a fourth extension part, a fifth extension part, and a sixth extension part connected in sequence;
wherein an orthographic projection of the first extension part on the base substrate extends along the first direction, a first end of the first extension part is connected to the first signal sub-line through a via hole, a second end of the first extension part is connected to the second signal sub-line through a via hole, and the orthographic projection of the first extension part on the base substrate covers the orthographic projection of the eighth active part in the second pixel driving circuit on the base substrate;
an orthographic projection of the second extension part on the base substrate at least partially overlaps with an orthographic projection of the ninth active part in the second pixel driving circuit on the base substrate, and an included angle between the orthographic projection of the second extension part on the base substrate and the orthographic projection of the first extension part on the base substrate is an obtuse angle;
an orthographic projection of the third extension part on the base substrate extends along the second direction, and the orthographic projection of the third extension part on the base substrate at least partially overlaps with the orthographic projection of the first connection part in the third pixel driving circuit on the base substrate; and
an orthographic projection of the fourth extension part on the base substrate extends along the first direction, and the orthographic projection of the fourth extension part on the base substrate at least partially overlaps with the orthographic projection of the twelfth active part in the third pixel driving circuit on the base substrate;
the second initial signal lines comprise a first initial signal sub-line, wherein an orthographic projection of the first initial signal sub-line on the base substrate at least partially overlaps with an orthographic projection of the fourth pixel driving circuit on the base substrate;
the first initial signal lines comprise a second initial signal sub-line corresponding to the fourth pixel driving circuit; and
the first connection line segment further comprises:
the fifth extension part, wherein an orthographic projection of the fifth extension part on the base substrate at least partially overlaps with the orthographic projection of the first initial signal sub-line on the base substrate; and
the sixth extension part, wherein an orthographic projection of the sixth extension part on the base substrate at least partially overlaps with the orthographic projection of the second initial signal sub-line on the base substrate.

16. The display panel according to claim 15, wherein the display panel further comprises light-emitting units, the fourth conductive layer further comprises electrode parts arranged in rows and columns, and the electrode parts are used to form electrodes of light-emitting units;
the electrode parts comprise red (R) electrode parts, green (G) electrode parts and blue (B) electrode parts alternately distributed in sequence along a same one of electrode rows;
in the same one of the electrode rows, two G electrode parts are arranged in the column direction between the R electrode part and the B electrode part; in two adjacent electrode rows, the electrode parts of a same color are located in different columns; and in two electrode rows with one electrode row therebetween, the electrode parts of a same color are located in a same column;
the electrode rows comprise a first electrode row, the first electrode row comprises a first R electrode part, a first G electrode part and a second G electrode part arranged in the column direction, and a first B electrode part that are arranged adjacently in the row direction, wherein the first G electrode part and the second G electrode part are located in a same electrode column, the first R electrode part forms the R electrode part, the first G electrode part and the second G electrode part form the G electrode part, and the first B electrode part forms the B electrode part;
wherein the first R electrode part is connected to the first pixel driving circuit, the second G electrode part is connected to the second pixel driving circuit, and the first B electrode part is connected to the third pixel driving circuit;
the orthographic projection of the first extension part on the base substrate is located between an orthographic projection of the first G electrode part on the base substrate and an orthographic projection of the second G electrode part on the base substrate;
the third conductive layer further comprises second connection parts, the second connection parts are connected to the electrode parts through via holes, the second connection parts comprise a first connection sub-part, and the first connection sub-part is connected to the first B electrode part;
the orthographic projection of the fourth extension part on the base substrate, the orthographic projection of the fifth extension part on the base substrate, and the orthographic projection of the sixth extension part on the base substrate are located on a side of an orthographic projection of the first B electrode part on the base substrate away from an orthographic projection of the first connection sub-part on the base substrate.

17. The display panel according to claim 3, wherein the pixel driving circuit comprises a driving transistor and a fourth transistor, a second electrode of the fourth transistor is connected to a second electrode of the driving transistor, and a first electrode of the fourth transistor is connected to a data line;
the display panel further comprises:
an active layer located between the base substrate and the first conductive layer, wherein the active layer comprises a thirteenth active part connected to a gate of the driving transistor, and an orthographic projection of the thirteenth active part on the base substrate extends along the second direction;
the second conductive layer further comprises third conductive parts, the third conductive parts are connected to a stable voltage source, and the third conductive part comprises:
a first conductive sub-part, wherein an orthographic projection of the first conductive sub-part on the base substrate extends along the second direction, and is located between the orthographic projection of the thirteenth active part on the base substrate and an orthographic projection of the data line on the base substrate.

18. The display panel according to claim 17, wherein the pixel driving circuit further comprises a second transistor, a first electrode of the second transistor is connected to a first electrode of the driving transistor, a second electrode of the second transistor is connected to a gate of the driving transistor, and the active layer further comprises:
a sixteenth active part used to form a first channel region of the second transistor;
a fourteenth active part used to form a second channel region of the second transistor; and
a fifteenth active part connected between the sixteenth active part and the fourteenth active part;
the third conductive part further comprises:
a second conductive sub-part connected to the first conductive sub-part, wherein an orthographic projection of the second conductive sub-part on the base substrate at least partially overlaps with an orthographic projection of the fifteenth active part on the base substrate.

19. The display panel according to claim 1, wherein the first direction is a row direction, the second direction is a column direction, the display panel further comprises pixel driving circuits arranged in rows and columns, and the pixel driving circuit comprises a driving transistor, a first transistor, a second transistor, a fourth transistor, a fifth transistor, a sixth transistor, and a seventh transistor; wherein
the first transistor is provided with a first electrode connected to a gate of the driving transistor, a second electrode connected to a first initial signal line, and a gate connected to a reset signal line;
the second transistor is provided with a first electrode connected to a first electrode of the driving transistor, a second electrode connected to the gate of the driving transistor, and a gate connected to a gate driving signal line;
the fourth transistor is provided with a second electrode connected to a second electrode of the driving transistor, a first electrode connected to a data line, and a gate connected to the gate driving signal line;
the fifth transistor is provided with a first electrode connected to a power line, a second electrode connected to the second electrode of the driving transistor, and a gate connected to an enable signal line;
the sixth transistor is provided with a first electrode connected to the first electrode of the driving transistor, and a gate connected to the enable signal line;
the seventh transistor is provided with a first electrode connected to a first initial signal line in a pixel driving circuit of a next row, a second electrode connected to a second electrode of the sixth transistor, and a gate connected to a reset signal line in the pixel driving circuit of the next row; and
the display panel comprises:
a first conductive layer comprising the enable signal line, the gate driving signal line, and the reset signal line, wherein an orthographic projection of the enable signal line on the base substrate, an orthographic projection of the gate driving signal line on the base substrate, and an orthographic projection of the reset signal line on the base substrate extend along the first direction; wherein
the enable signal line comprises a seventh extension part and an eighth extension part alternately connected in sequence; in the second direction, a size of an orthographic projection of the seventh extension part on the base substrate is smaller than a size of an orthographic projection of the eight extension part on the base substrate; and the orthographic projection of the seventh extension part on the base substrate intersects with the orthographic projection of the data line on the base substrate;
the gate driving signal line comprises a ninth extension part and a tenth extension part alternately connected in sequence; in the second direction, a size of an orthographic projection of the ninth extension part on the base substrate is smaller than a size of an orthographic projection of the tenth extension part on the base substrate; and the orthographic projection of the ninth extension part on the base substrate intersects with the orthographic projection of the data line on the base substrate; and
the reset signal line comprises an eleventh extension part and a twelfth extension part alternately connected in sequence; in the second direction, a size of an orthographic projection of the eleventh extension part on the base substrate is smaller than a size of an orthographic projection of the twelfth extension part on the base substrate; and the orthographic projection of the eleventh extension part on the base substrate intersects with the orthographic projection of the data line on the base substrate.

20. A display device, comprising a display panel wherein the display panel comprises:
a base substrate;
a third conductive layer located on one side of the base substrate, wherein the third conductive layer comprises first signal lines, orthographic projections of the first signal lines on the base substrate are spaced apart in a first direction and extend along a second direction, and the first direction intersects with the second direction; and
a fourth conductive layer located on one side of the third conductive layer away from the base substrate, wherein the fourth conductive layer comprises connection line segments, orthographic projections of the connection line segments on the base substrate extend along the first direction, and a same one of the connection line segments is connected to multiple ones of the first signal lines through via holes, respectively.
